(19) United States
(12) Patent Application Publication
(10) Pub. No.: US 2006/0258067 A1
(43) Pub. Date: Nov. 16, 2006

(54) Device for protecting against electrostatic discharge

(75) Inventors: Chan-Hee Jeon, Suwon-si (KR); Kyoung-Sik Im, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/430,916

(22) Filed: May 10, 2006

(30) Foreign Application Priority Data
May 10, 2005 (KR) 2005-38995

(51) Int. Cl. H01L 21/84; H01L 29/74

(52) U.S. Cl. 438/154; 257/173

(57) ABSTRACT

A device, for protecting against electrostatic discharge, structured as a PNPN junction, includes: first and second conductivity type regions formed in a substrate, contacting each other; a first diffusion layer of second conductivity type dopants formed in the first conductivity type region and electrically connected to an anode; a second diffusion layer of first conductivity type dopants formed in the second conductivity type region and electrically connected to a cathode; and at least one of (A) a third diffusion layer of first conductivity type dopants formed in the first conductivity type region between the first diffusion layer and the second conductivity type region and electrically connected to the anode through a first external resistor, and a (B) fourth diffusion layer of second conductivity type dopants formed in the second conductivity type region between the second diffusion layer and the first conductivity type region and electrically connected to the cathode through a second external resistor.

### PRIORITY STATEMENT

This U.S. non-provisional patent application claims priority under 35 U.S.C. §119 of Korean Patent Application 2005-38995 filed on May 10, 2005, the entire contents of which are hereby incorporated by reference.

### BACKGROUND

The subject matter described herein is concerned with semiconductor devices, and devices for protecting a semiconductor circuit from abnormal electrostatic discharge and electrical overstress.

Semiconductor integrated circuits are usually sensitive to transient electrostatic discharge (ESD) and continuous electrical overstress (EOS) caused by contact with human bodies or abnormalities of apparatuses. Since the ESD or EOS typically manifests as sudden high voltages or large currents to which the integrated circuits are exposed, they cause breakdown of insulation films, destruction of junctions, and/or short-circuiting of metal interconnections in the integrated circuits, resulting in degraded operational characteristics and/or failures.

Devices for protecting against ESD (hereinafter, referred to as “ESD protection devices”) function to shunt such high voltages or large currents away from the integrated circuits so as to prevent them from inflow thereto. There have been proposed various kinds of the ESD protection devices, e.g., GGNMOS transistors, PN-junction diodes, bipolar junction transistors, silicon-controlled rectifiers (SCR), and so forth.

The GGNMOS and bipolar junction transistors discharge charges through positive feedback mechanisms by the effects of avalanche breakdown at drain and collector junctions and by charge injection at source and emitter junctions, respectively. But they are insufficient to effectively combat the invasive surges by the phenomena of ESD and EOS since it is difficult for them to overcome concentrations of electric fields on the drain and collector junctions

As contrasted with GGNMOS and bipolar junction transistors, the SCR is advantageous to preventing the concentration of electric fields because it is able to discharge electrostatic energy through double injection between wide junctions of wells doped with different conductivity types. The SCR may be effectively used as an ESD protection device for an input/output pad as it is able to discharge electrostatic energy in a short time by a strong snapback operation. But the SCR itself can be damaged due to EOS surge and latch-up arising from a low holding voltage when the SCR is employed at a power source pad.

FIG. 1 is a sectional diagram showing a general SCR 100 according to the Related Art.

In the SCR 100 shown in FIG. 1, an N-well 10 and a P-well 20 are formed in a semiconductor substrate, contacting each other. A first diffusion layer 12 with a high concentration of P-type dopants is formed in the N-well 10, and a second diffusion layer 22 with a concentration of N-type dopants is formed in the P-well 20. The N-well 10 and the first diffusion layer 12 are connected to an anode ANODE, while the P-well 20 and the second diffusion layer 22 are connected to a cathode CATHODE. The N-well 10 is connected to the anode ANODE through a third diffusion layer 14 with a high concentration of N-type dopants that is formed therein. The P-well 20 is connected to the cathode CATHODE through a fourth diffusion layer 24 with a high concentration of P-type dopants that is formed therein. Therefore, the first diffusion layer 12 is settled in the N-well 10 between the third diffusion layer 14 and the P-well 20. The second diffusion layer 22 is settled in the P-well 20 between the fourth diffusion layer 24 and the N-well 10.

As a whole, the SCR 100 shown in FIG. 1 is composed of a PNP bipolar transistor Q1 and an NPN bipolar transistor Q2. The transistor Q1 includes the first diffusion layer 12 as the emitter region, the N-well 10 as the base region, and the P-well 20 as the collector region. The transistor Q2 includes the second diffusion layer 22 as the emitter region, the P-well 20 as the base region, and the N-well 10 as the collector region.

If there is inflow of an ESD current toward the anode ANODE due to ESD, the NP junction of the N-well 10 and the P-well 20, which is being reverse-biased, is forced to be breakdown to make the PNP and NPN bipolar transistors, Q1 and Q2, turned on. During this, the ESD current is discharged through the cathode CATHODE by a positive feedback operation for which the reverse-biased NP junction acts as a forward-biased junction. In other words, a voltage inducing the breakdown at the reverse-biased NP junction becomes a triggering voltage of the SCR 100. And, when the SCR 100 is triggered on thereby, the ESD current is promptly discharged through a strong snapback operation by which the voltage over the NP junction is reduced abruptly.

FIG. 2 is a current-voltage graphic diagram showing a characteristic of the general SCR 100.

As can be seen from FIG. 2, if a voltage by ESD, which is higher than the triggering voltage of the SCR 100, surges on the anode ANODE, the SCR 100 is triggered on to make the voltage lowered by the snapback operation (period a). During this, the voltage falls down to a holding voltage V_{H} by the snapback operation. When an ESD larger much than a holding current I_{H} is supplied to the SCR 100, the SCR 100 is put into a latch-up operation period b to discharge the ESD current under the condition of low impedance. Such low impedance condition does not change until the ESD voltage falls down under the holding voltage V_{H} or the ESD current is reduced to less than the holding current I_{H}. This function of the SCR 100 is effective for an input/output pad to which a low voltage or a pulsed voltage. But the Related Art SCR would be damaged due to low holding voltage V_{H} when the SCR 100 is employed at a power source pad to which a constant voltage is supplied.

### SUMMARY

While the Related Art SCR can shunt charge under the condition of low impedance, its low holding voltage thereof renders the Related Art SCR inadequate for an ESD protection device adaptable to a pad that is operable with a normally high voltage.

Accordingly, one or more embodiments of the present invention provide an ESD protection device that is substantially not degraded by a high holding voltage therein, and that can shunt a substantial amount of charge under the condition of low impedance.

Additional features and advantages of the present invention will be more fully apparent from the following detailed description of example embodiments, the accompanying drawings and the associated claims.

### BRIEF DESCRIPTION OF THE DRAWINGS

The accompanying drawings are not to be considered as drawn to scale unless explicitly noted. In the drawings, the thickness of layers and regions are exaggerated for clarity.

The accompanying drawings are included to provide a further understanding of the present invention, and are incorporated in and constitute a part of this specification. The drawings illustrate example embodiments of the present invention and, together with the description, serve to explain principles of the present invention. In the figures:

FIG. 1 is a sectional diagram showing a general silicon-controlled rectifier (SCR), according to the Related Art;

FIG. 2 is a current-voltage graphic diagram showing a characteristic of the general SCR, of Related Art FIG. 1;

FIG. 3 is a sectional diagram illustrating an ESD protection device in accordance with an example embodiment of the present invention;

FIG. 4 is a current-voltage graphic diagram showing a characteristic of the ESD protection device of FIG. 3;

FIGS. 5 and 6 are sectional diagrams comparatively illustrating current paths each operable in the Related Art SCR of FIG. 1 and the presently disclosed ESD protection device of FIG. 3, depicting simulation results thereof, respectively;

FIG. 7 is a sectional diagram illustrating an ESD protection device in accordance with an example embodiment of the present invention;

FIG. 8 is a sectional diagram illustrating an ESD protection device in accordance with an example embodiment of the present invention;

FIG. 9 is a sectional diagram illustrating an ESD protection device in accordance with an example embodiment of the present invention;

FIG. 10 is a sectional diagram illustrating an ESD protection device in accordance with an example embodiment of the present invention;

FIG. 11 is a sectional diagram illustrating an ESD protection device in accordance with an example embodiment of the present invention; and

FIG. 12 is a sectional diagram illustrating an ESD protection device in accordance with an example embodiment of the present invention.

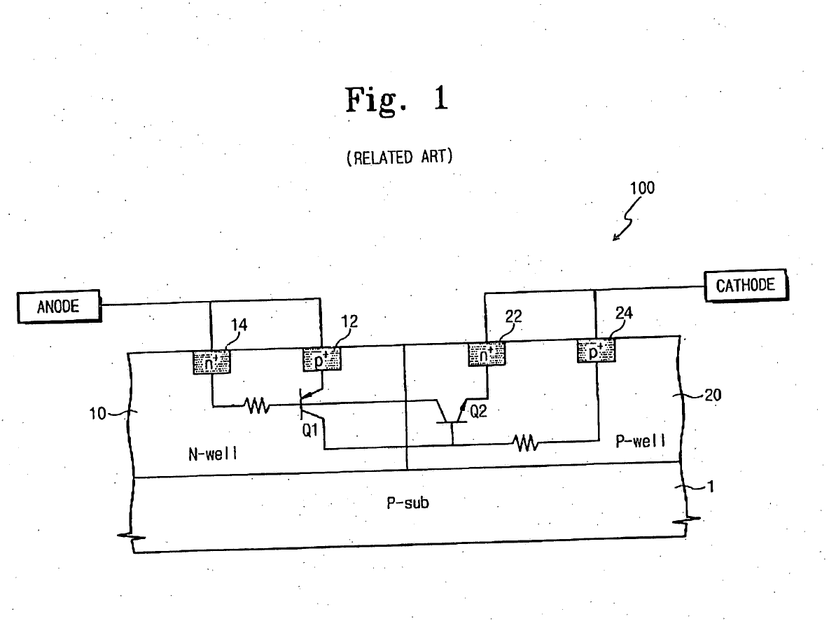

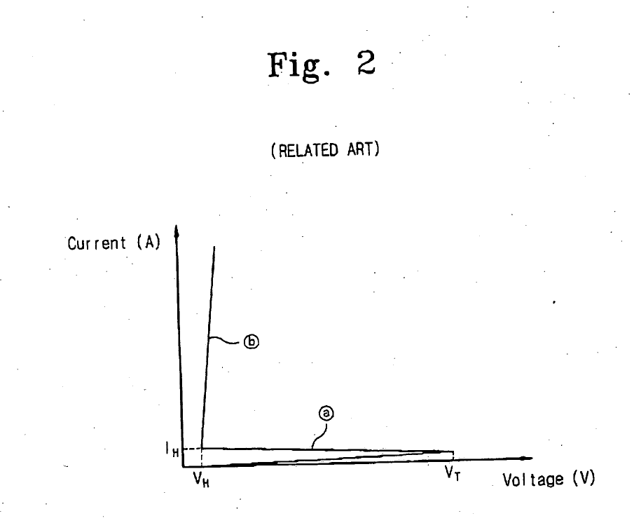

### DETAILED DESCRIPTION OF EXAMPLE EMBODIMENTS

It will be understood that if an element or layer is referred to as being “on,” “against,” “connected to” or “coupled to” another element or layer, then it can be directly on, against connected or coupled to the other element or layer, or intervening elements or layers may be present. In contrast, if an element is referred to as being “directly on”, “directly connected to” or “directly coupled to” another element or layer, then there are no intervening elements or layers present. Like numbers refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular example embodiments only and is not intended to be limiting of the present invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

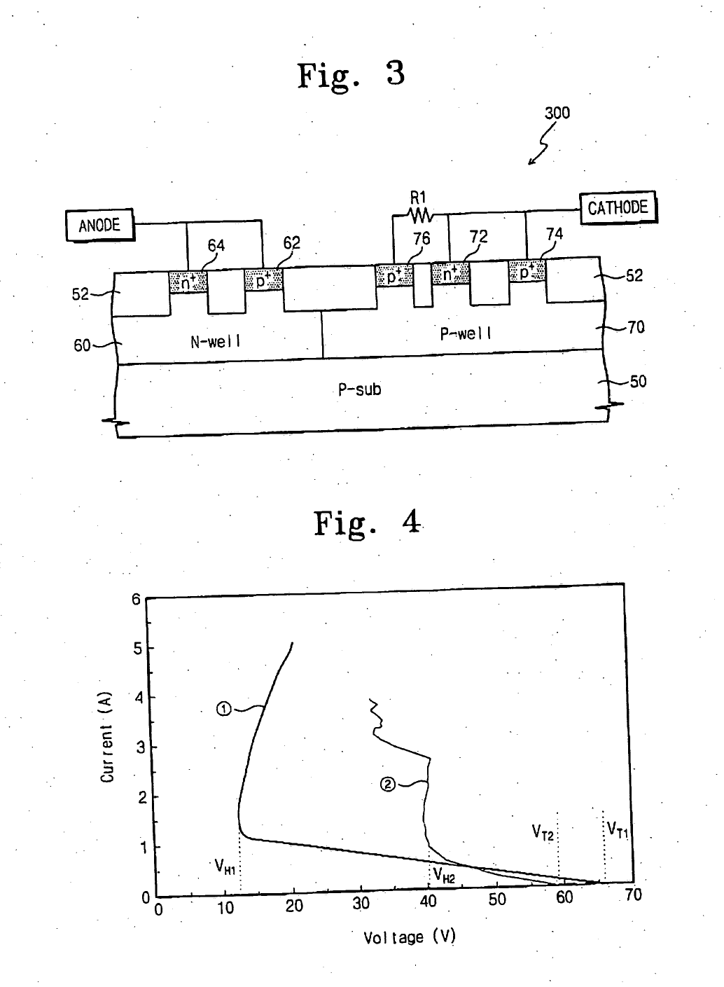

FIG. 3 is a sectional diagram illustrating an ESD protection device 300 in accordance with an example embodiment of the present invention.

Referring to the ESD protection device 300 of FIG. 3, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

The N-well 60 is connected to the anode ANODE through a third diffusion layer 64 with a high concentration of N-type dopants, and the P-well 70 is connected to the cathode CATHODE through a fourth diffusion layer 74 with a high concentration of P-type dopants. Therefore, the first diffusion layer 62 of P-type dopants is settled between the third diffusion layer 64 of N-type dopants and the P-well 70. The second diffusion layer 72 of N-type dopants is settled between the fourth diffusion layer 74 and the N-well 60.

In FIG. 3, a fifth diffusion layer 76 with a high concentration of P-type dopants is formed in the P-well 70 between the second diffusion layer 72 and the N-well 60, being connected to the cathode CATHODE. Between the fifth diffusion layer 76 and the cathode CATHODE is connected an external resistor R1. This structure uses the fifth diffusion layer 76 of P-type dopants, which is close to the edge of the P-well 70 and connected to the cathode CATHODE through the resistor R1, as a floated diffusion layer, so that it is possible to raise the holding voltage therein.

As such, the ESD protection device 300 may be similar to a general SCR. However, the device 300 is configured with the feature that the fifth diffusion layer 76 with a high concentration of N-type dopants is additionally comprised between the second diffusion layer 72 of N-type dopants and the N-well 60 and connected to the cathode CATHODE through the external resistor R1. With this structure, the fifth diffusion layer 76 functions as a well-guarding region under a normal operation thereof, restraining an abnormal latch-up effect. Further, in the emergency with ESD or EOS, as the external resistor R1 acts as a current-limiting element to make the fifth diffusion layer 76 operate instantly as an electrically floated diffusion layer, the well resistance increases to raise the holding voltage therein.

The ESD protection device 300 of FIG. 3 also can be described as having an PNP_{N}^{P} junction structure. The notation NP denotes a junction between a region of N-type dopants conductivity and a region of P-type dopants conductivity, arranged electrically in series (e.g., the junction between the N-well 60 and the P-well 70), and vice-versa for the notation PN (e.g., the junction between the first diffusion layer 62 and the N-well 60). The notation P_{N}^{P} denotes a PP junction (e.g., the junction between the P-well 70 and the fifth diffusion layer 76) and a PN junction (e.g., the junction between the P-well 70 and the second diffusion layer 72).

FIG. 4 is a current-voltage graphic diagram showing a characteristic of the ESD protection device 300. In the graph of FIG. 4, the curve \textcircled{1} depicts a current-voltage (I-V) characteristic of a general SCR. The curve \textcircled{2} depicts an I-V characteristic of the ESD protection device, according to the first embodiment of the present invention, which further includes a high-concentration diffusion layer (e.g., the fifth diffusion layer 76) that is formed in a width of 2 μm and connected to the cathode CATHODE through an external resistor (e.g., R1).

Referring to FIG. 4, the ESD protection device 300 is able to raise the holding voltage by further including the electrically floated diffusion layer 76 in the P-well 70 relative to the Related Art SCR 100. From the graph, it can be seen that the holding voltage V_{H2} of the ESD protection device 300 is higher than the holding voltage V_{H1} of the Related Art SCR 100. Thus, although there is generated a latch-up effect after the ESD protection device is triggered up, it is possible to protect the ESD protection device from EOS surges because the ESD protection device returns to its normal condition in a short time by the high holding voltage.

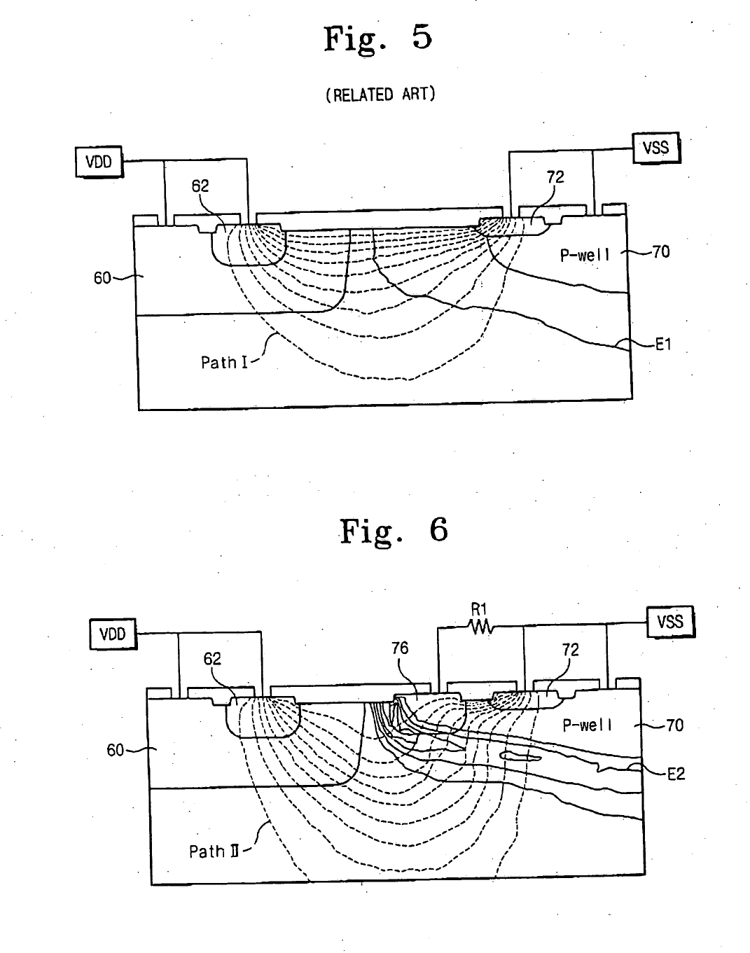

FIGS. 5 and 6 are sectional diagrams comparatively illustrating current paths each operable in the Related Art SCR 100 and the presently disclosed ESD protection device 300 depicting simulation results thereof respectively. The simulation was conducted according to the assumption of connecting the anode ANODE to a first power source VDD while connecting the cathode CATHODE to a second power source VSS.

Referring to FIG. 5 as the Related Art case, after the SCR 100 was triggered on, the current flowed from the first diffusion layer 62 of P-type dopants to the second diffusion layer 72 of N-type dopants by way of the N-well 60 and the P-well 70 (path I). In FIG. 6, in the presently disclosed ESD protection device 300 (which has the fifth diffusion layer 76 settled between the second diffusion layer 72 and the N-well 60 and that is connected to the second power source VSS through the resistor R1), the peak of electric field appeared at the edge of the fifth diffusion layer 76 under the emergency of ESD or EOS and thereby the current path (path II) was formed in a deep region of the substrate. Without being bound by theory, that result is regarded as arising due to the external resistor R1 acting as a current-limiting resistor. Thus, the parallel circuit leg formed by the fifth diffusion layer 76 and the external resistor R1 increases on-resistance of the ESD protection device 300, resulting in elevation of the holding voltage therein. The structure associated with the external resistor R1 as the current-limiting element may be otherwise implemented, e.g., as an N-type dopants diffusion layer formed in the N-well 60, or a P-type dopants diffusion layer in the P-well 70.

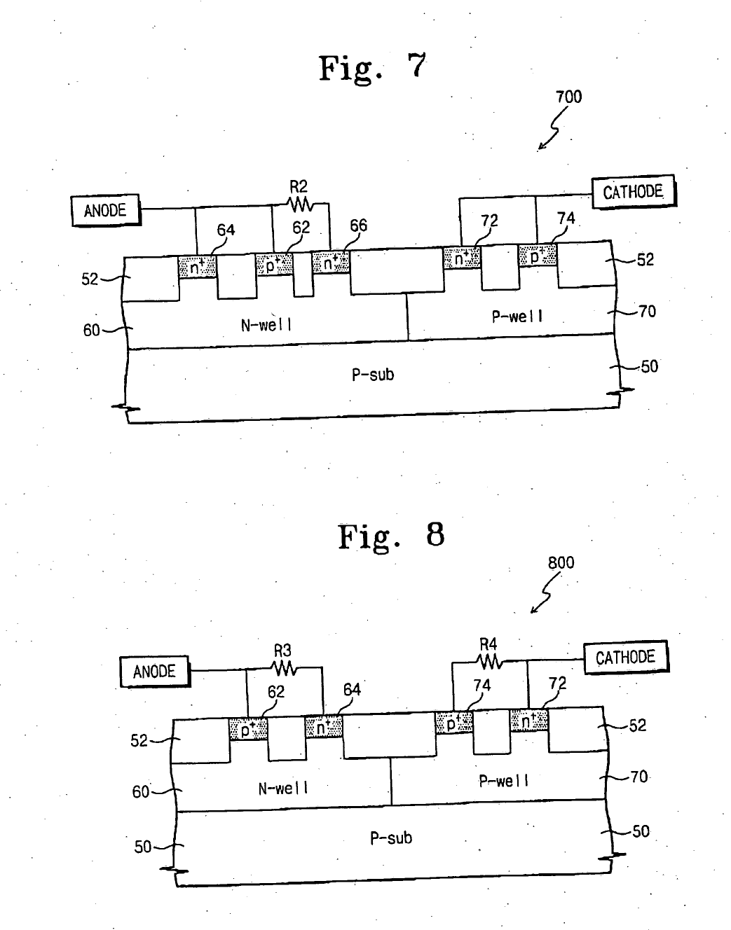

FIG. 7 is a sectional diagram illustrating an ESD protection device 700 in accordance with an example embodiment of the present invention.

Referring to the ESD protection device 700 of FIG. 7, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

The N-well 60 is connected to the anode ANODE through a third diffusion layer 64 with a high concentration of N-type dopants, and the P-well 70 is connected to the cathode CATHODE through a fourth diffusion layer 74 with a high concentration of P-type dopants. Therefore, in the ESD protection device 700, the first diffusion layer 62 of P-type dopants is settled between the third diffusion layer 64 of N-type dopants and the P-well 70. The second diffusion layer 72 of N-type dopants is settled between the fourth diffusion layer 74 and the N-well 60.

A fifth diffusion layer 66 with a high concentration of N-type dopants is formed in the N-well 60 between the first diffusion layer 62 and the P-well 70, being connected to the anode ANODE. Between the fifth diffusion layer 66 and the anode ANODE is connected an external resistor R2.

The ESD protection device 700 of FIG. 7 also can be described as having an _{N}^{P}NPN junction structure. The notation NP (again) denotes a junction between a region of N-type dopants conductivity and a region of P-type dopants conductivity, arranged electrically in series (e.g., the junction between the N-well 60 and the P-well 70), and (again) vice-versa for the notation PN (e.g., the junction between the P-well 70 and the second diffusion layer 72). The notation _{N}^{P}N denotes a PN junction (e.g., the junction between the first diffusion layer 62 and the N-well 60) and an NN junction (e.g., the junction between the fifth diffusion layer 66 and the N-well 60).

FIG. 8 is a sectional diagram illustrating an ESD protection device 800 in accordance with an example embodiment of the present invention.

Referring to the ESD protection device 800 of FIG. 8, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

In FIG. 8, the N-well 60 is connected to the anode ANODE through a third diffusion layer 64 with a high concentration of N-type dopants, and the P-well 70 is connected to the cathode CATHODE through a fourth diffusion layer 74 with a high concentration of P-type dopants. In the ESD protection device 800, the third diffusion layer 64 of N-type dopants is disposed between the first diffusion layer 62 of P-type dopants and the P-well 70, while the fourth diffusion layer 74 is disposed between the second diffusion layer 72 of N-type dopants and the N-well 60. A first external resistor R3 is connected between the third diffusion layer 64 and the anode ANODE, while a second external resistor R4 is connected between the fourth diffusion layer 74 and the cathode CATHODE.

The ESD protection device 300 is configured to increase resistance between the N-well 60 and the anode ANODE, and between the P-well 70 and the cathode CATHODE, which can quickly discharge substantial amounts of current by weak snapback and latch-up operations after the PNPN junction is triggered on.

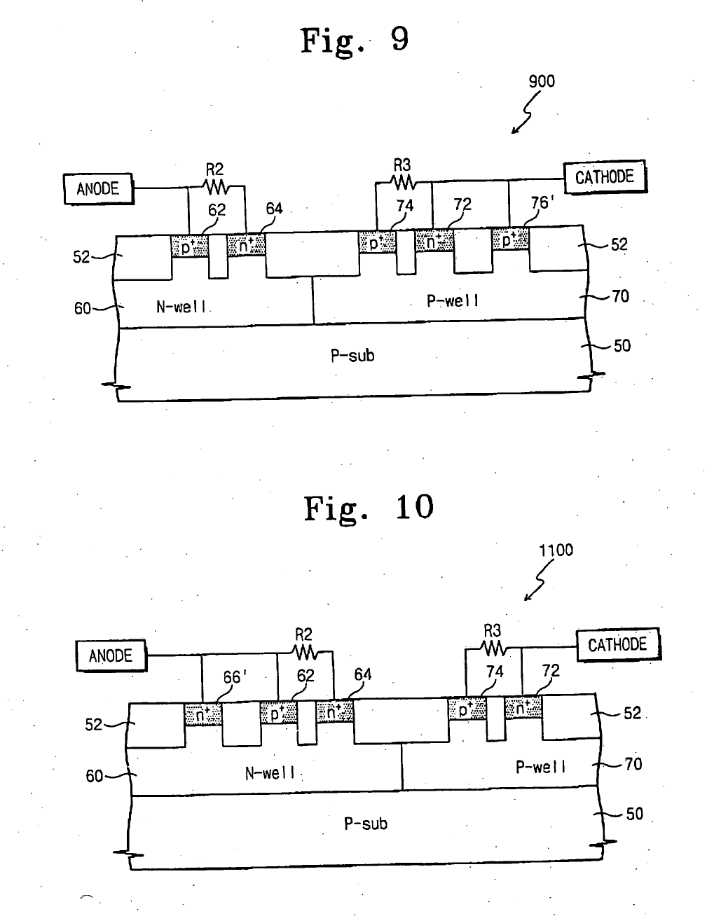

FIG. 9 is a sectional diagram illustrating an ESD protection device 900 in accordance with an example embodiment of the present invention.

Referring to the ESD protection device of FIG. 9, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

In FIG. 9, a third diffusion layer 64 with a high concentration of N-type dopants is formed in the N-well 60 between the first diffusion layer 62 and the P-well, while a fourth diffusion layer 74 with a high concentration of P-type dopants is formed in the P-well 70 between the second diffusion layer 72 and the N-well 60. The third diffusion layer 64 is connected to the anode ANODE and the fourth diffusion layer 74 is connected to the cathode CATHODE. A first external resistor R2 is connected between the third diffusion layer 64 and the anode ANODE, while a second external resistor R3 is connected between the fourth diffusion layer 74 and the cathode CATHODE. The ESD protection device 900, further includes a fifth diffusion layer 76′ of P-type dopants that is formed in the P-well 70 and electrically connected to the cathode CATHODE. The fifth diffusion layer 76′ is spaced apart from the N-well 60 more than the second diffusion layer 72. More specifically, the second diffusion layer 72 is disposed between the N-well 60 and the fifth diffusion layer 76′.

FIG. 10 is a sectional diagram illustrating an ESD protection device 1000 in accordance with an example embodiment of the present invention.

Referring to the ESD protection device 1000 of FIG. 10, as compared to the ESD protection device 900, device 1000 is configured with a fifth diffusion layer 66′ of N-type dopants that is formed in the N-well 60 and electrically connected to the anode ANODE. In detail, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

A third diffusion layer 64 with a high concentration of N-type dopants is formed in the N-well 60 between the first diffusion layer 62 and the P-well, while a fourth diffusion layer 74 with a high concentration of P-type dopants is formed in the P-well 70 between the second diffusion layer 72 and the N-well 60. The third diffusion layer 64 is connected to the anode ANODE and the fourth diffusion layer 74 is connected to the cathode CATHODE. A first external resistor R2 is connected between the third diffusion layer 64 and the anode ANODE, while a second external resistor R3 is connected between the fourth diffusion layer 74 and the cathode CATHODE. The ESD protection device 1000 further includes the fifth diffusion layer 66′ of N-type dopants that is formed in the N-well 60 and electrically connected to the anode ANODE. The first diffusion layer 62 is disposed between the P-well 70 and the fifth diffusion layer 66′.

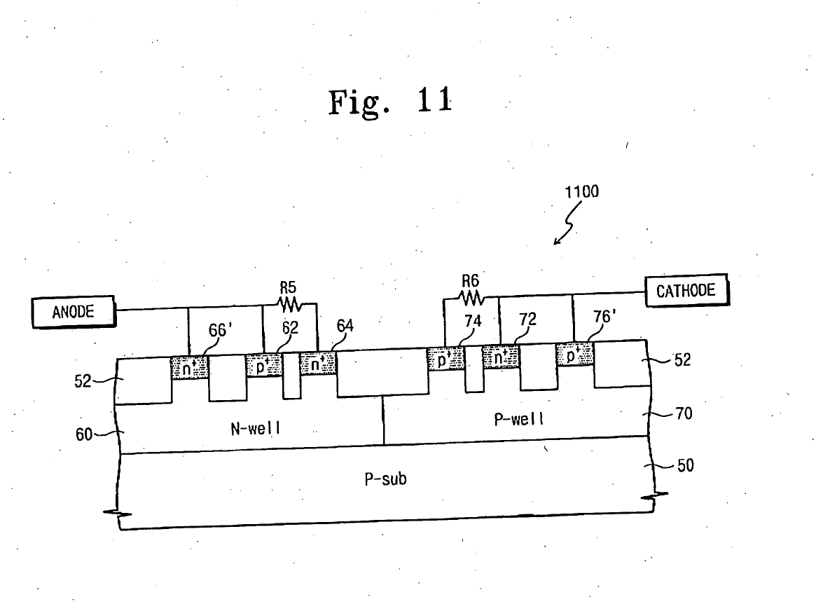

FIG. 11 is a sectional diagram illustrating an ESD protection device 1100 in accordance with an example embodiment of the present invention.

Referring to FIG. 11, the ESD protection device 1100 further includes a fifth diffusion layer 66′ with a high concentration of N-type dopants, formed in the N-well 60 and electrically connected to the anode ANODE, and a sixth diffusion layer 76′ with a high concentration of P-type dopants formed in the P-well 70 and electrically connected to the cathode CATHODE.

In FIG. 11, an N-well 60 and a P-well 70 are formed in a semiconductor substrate 50, contacting each other. A first diffusion layer 62 with a high concentration of P-type dopants is formed in the N-well 70, and a second diffusion layer 72 with a concentration of N-type dopants is formed in the P-well 70. The N-well 60 and the first diffusion layer 62 of P-type dopants are electrically connected to an anode ANODE, while the P-well 70 and the second diffusion layer 72 of N-type dopants are electrically connected to a cathode CATHODE.

Also, in FIG. 11, a third diffusion layer 64 with a high concentration of N-type dopants is formed in the N-well 60 between the first diffusion layer 62 and the P-well, while a fourth diffusion layer 74 with a high concentration of P-type dopants is formed in the P-well 70 between the second diffusion layer 72 and the N-well 60. The third diffusion layer 64 is connected to the anode ANODE and the fourth diffusion layer 74 is connected to the cathode CATHODE. A first external resistor R5 is connected between the third diffusion layer 64 and the anode ANODE, while a second external resistor R6 is connected between the fourth diffusion layer 74 and the cathode CATHODE. The fifth diffusion layer 66′ of N-type dopants is formed in the N-well 60 and electrically connected to the anode ANODE, while the sixth diffusion layer 76′ is formed in the P-well 70 and electrically connected to the cathode CATHODE. The first diffusion layer 62 is disposed between the P-well 70 and the fifth diffusion layer 66′, while the second diffusion layer 72 is disposed between the N-well 60 and the sixth diffusion layer 76′.

The ESD protection device 1100 of FIG. 11 also can be described as having an _{N}^{P}NP_{N}^{P} junction structure.

As such, the various ESD protection devices according to the foregoing example embodiments of the present invention are available to be coupled with, e.g., input/output pads or power source pads in semiconductor integrated-circuit chips fabricated by CMOS manufacturing processes, for the purpose of protecting the chips from ESD or EOS.

Throughout the example embodiments described herein, alternatively the anode ANODE may be connected to an input/output pad or a power source pad while the cathode CATHODE may be connected to a ground pad. Also in the alternative, the ANODE my be connected to the diffusion layers in the P-well and the CATHODE may be connected to the diffusion layers in the N-well.

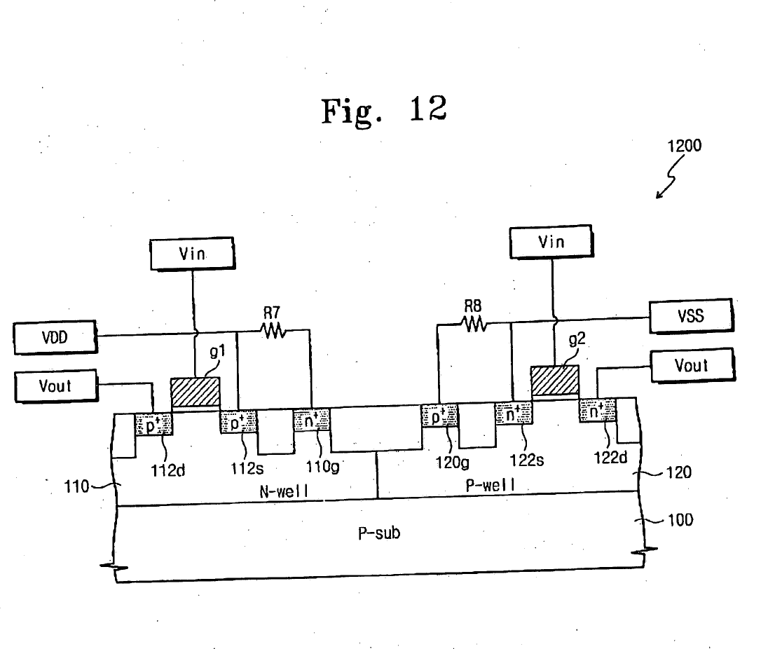

FIG. 12 is a sectional diagram illustrating an ESD protection device 1200 in accordance with an example embodiment of the present invention.

Referring to FIG. 12, the ESD protection device 1200 (which can be incorporated into a semiconductor chip fabricated by CMOS process) includes an N-well 110 and a P-well 120 formed in a substrate 100. The N-well 110 and the P-well 120 form a junction in the substrate 100. A PMOS transistor is formed in the N-well 110 while an NMOS transistor is formed in the P-well 120. The PMOS transistor includes P-type dopants source and drain regions, 112s and 112d, formed in the N-well 110, and a gate electrode g1 formed over the channel region confined between the source and drain regions 112s and 112d. The NMOS transistor includes N-type dopants source and drain regions, 122s and 122d, formed in the P-well 120, and a gate electrode g2 formed over the channel region confined between the source and drain regions 122s and 122d.

In a general CMOS inverter according to the Related Art, the source region 112s of the PMOS transistor is connected to the first power source VDD, but the source region 122s of the NMOS transistor is connected to the second power source VSS. And, the drain regions, 112d and 122d, of the PMOS and NMOS transistors are connected to an output terminal Vout, while the gate electrodes g1 and g2 are connected to an input terminal Vin. A Related Art CMOS device employs well-guarding regions around the edges of wells in order to prevent damaging the device due to latch-up effect. Charges that flow into such wells are discharged out of the device.

The ESD protection device 1200 adopts such well-guarding structure. The source and well-guarding regions are connected to the first or second power sources in common through a resistor, substantially (if not completely) protecting the device from ESD or EOS.

In detail in FIG. 12, an N-type dopants guarding region 110g with a high concentration of N-type dopants is formed at the edge of the N-well 110 and a P-type dopants guarding region 120g with a high concentration of P-type dopants is formed at the edge of the P-well 120. The N-type dopants guarding region 110g is connected to the first power source VDD together with the source region 112s of the PMOS transistor, while the P-type dopants guarding region 120g is connected to the second power source VSS together with the source region 122s of the NMOS transistor. A first external resistor R7 is connected between the N-type dopants guarding region 110g and the first power source VDD, while a second external resistor R8 is connected between the P-type dopants guarding region 120g and the second power source VSS.

As can be seen from the structure of FIG. 12, the source region 112s of the PMOS transistor, which is adjacent to the N-type dopants guarding region 110g, corresponds to the first diffusion layer 62 of P-type dopants shown in FIG. 8. And the source region 122s of the NMOS transistor, which is adjacent to the P-type dopants guarding region 120g, corresponds to the second diffusion layer 72 of N-type dopants shown in FIG. 9.

In the ESD protection structure shown in FIG. 12, the well-guarding regions, 110g and 120g help to reduce (if not prevent) the latch-up effect in the CMOS device under the condition of DC operation, and the external resistors, R7 and R8, function as current-limiting resistors. Therefore, the structure of FIG. 12 is effectively operable as an ESD protection device.

One or more embodiments of the present invention provide an ESD protection device operable with high holding voltages and capable of fast current-discharging in a relatively small layout area. In such an ESD protection device, on-resistance is raised by the external resistors connected to the electrically floated diffusion layers or the wells when the NP junction is induced to exhibit breakdown that causes current flow between the anode and the cathode. On the other hand, the N-type dopants or P-type dopants diffusion layers with a high concentration of respective dopants are formed in active fields, being separated from each other by field isolation films 52, so that the ESD current path (e.g., path II shown in FIG. 6) becomes modified or longer due to the presence of the field isolation films 52, thereby further increasing the on-resistance therein.

One or more embodiments of the present invention provide an ESD protection device (having the high holding voltage and the capability of fast current-discharging) that also is able to protect the itself from ESD or EOS despite being coupled to a power source pad to which a voltage greater than a reference level is supplied, as well as an input/output pad to which a low-voltage pulse is applied.

In addition, via reducing a triggering voltage in the ESD protection device by adjusting an interval between the high-concentration diffusion layer and the well edge, one or more embodiments of the present invention can improve the efficiency of protecting an integrated circuit chip from the emergency of ESD or EOS.

While there has been illustrated and described what are presently considered to be example embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Therefore, it is intended that the present invention not be limited to the particular example embodiments disclosed, but that the present invention include all embodiments falling within the scope of the appended claims.

What is claimed is:

1. A device for protecting against electrostatic discharge, the device comprising:
first and second conductivity type regions formed in a substrate, contacting each other;
a first diffusion layer of second conductivity type dopants formed in the first conductivity type region and electrically connected to an anode;
a second diffusion layer of first conductivity type dopants formed in the second conductivity type region and electrically connected to a cathode; and
at least one of a third diffusion layer of first conductivity type dopants formed in the first conductivity type region between the first diffusion layer and the second conductivity type region and electrically connected to the anode through a first external resistor, and a fourth diffusion layer of second conductivity type dopants formed in the second conductivity type region between the second diffusion layer and the first conductivity type region and electrically connected to the cathode through a second external resistor.

2. The device as set forth in claim 1, further comprising a fifth diffusion layer of first conductivity type dopants formed in the first conductivity type region and electrically connected to the anode,
wherein the first diffusion layer is disposed between the fifth diffusion layer and the second conductivity type region.

3. The device as set forth in claim 1, further comprising a fifth diffusion layer of second conductivity type dopants formed in the second conductivity type region and electrically connected to the cathode,
wherein the second diffusion layer is disposed between the fifth diffusion layer and the first conductivity type region.

4. The device as set forth in claim 1, wherein the anode is connected to a power source pad and the cathode is connected to a ground pad.

5. The device as set forth in claim 1, wherein the anode is connected to an input/output pad and the cathode is connected to a ground pad.

6. A device for protecting against electrostatic discharge, the device comprising:
first and second conductivity type regions formed in a substrate, contacting each other;
a first diffusion layer of second conductivity type dopants formed in the first conductivity type region;
a second diffusion layer of first conductivity type dopants formed in the second conductivity type region; and
at least one of the following
a third diffusion layer of first conductivity type dopants formed in the first conductivity type region between the first diffusion layer and the second conductivity type region, and
a fourth diffusion layer of second conductivity type dopants formed in the second conductivity type region between the second diffusion layer and the first conductivity type region;
wherein the first and third diffusion layers are connected to an anode while the second and fourth diffusion layers are connected to a cathode,
wherein the third diffusion layer is connected to the anode through a first external resistor and the fourth diffusion layer is connected to the cathode through a second external resistor.

7. The device as set forth in claim 6, further comprising a fifth diffusion layer of first conductivity type dopants formed in the first conductivity type region and electrically connected to the anode,
wherein the first diffusion layer is interposed between the fifth diffusion layer and the second conductivity type region.

8. The device as set forth in claim 6, further comprising a fifth diffusion layer of second conductivity type dopants formed in the second conductivity type region and electrically connected to the cathode,
wherein the second diffusion layer is interposed between the fifth diffusion layer and the first conductivity type region.

9. The device as set forth in claim 6, further comprising:
a fifth diffusion layer of first conductivity type dopants formed in the first conductivity type region and electrically connected to the anode; and
a sixth diffusion layer of second conductivity type dopants formed in the second conductivity type region and electrically connected to the cathode,
wherein the first diffusion layer is interposed between the fifth diffusion layer and the second conductivity type region, while the second diffusion layer is interposed between the sixth diffusion layer and the first conductivity type region.

10. The device as set forth in claim 6, wherein the anode is connected to a power source pad and the cathode is connected to a ground pad.

11. The device as set forth in claim 6, wherein the anode is connected to an input/output pad and the cathode is connected to a ground pad.

12. A device for protecting against electrostatic discharge, the device comprising:
first and second conductivity type regions formed in a substrate, contacting each other;
a first diffusion layer of second conductivity type dopants formed in the first conductivity type region and electrically connected to an anode;
a second diffusion layer of first conductivity type dopants formed in the second conductivity type region and electrically connected to a cathode;
a third diffusion layer of first conductivity type dopants formed in the first conductivity type region and electrically connected to the anode;
a fourth diffusion layer of second conductivity type dopants formed in the second conductivity type region and electrically connected to a cathode; and
a fifth diffusion layer of first conductivity type dopants formed in the first conductivity type region between the first diffusion layer and the second conductivity type region and electrically connected to the anode,
wherein the first diffusion layer is disposed between the third diffusion layer and the second conductivity type region, and the second diffusion layer is disposed between the fourth diffusion layer and the first conductivity type region,
wherein the fifth diffusion layer is connected to the anode through an external resistor.

13. The device as set forth in claim 12, wherein the anode is connected to a power source pad and the cathode is connected to a ground pad.

14. The device as set forth in claim 12, wherein the anode is connected to an input/output pad and the cathode is connected to a ground pad.

15. A device for protecting against electrostatic discharge, comprising:
first and second conductivity type regions formed in a substrate, contacting each other;
a first diffusion layer of second conductivity type dopants formed in the first conductivity type region and electrically connected to an anode;
a second diffusion layer of first conductivity type dopants formed in the second conductivity type region and electrically connected to a cathode;
a third diffusion layer of first conductivity type dopants formed in the first conductivity type region and electrically connected to the anode;
a fourth diffusion layer of second conductivity type dopants formed in the second conductivity type region and electrically connected to the cathode; and
a fifth diffusion layer of second conductivity type dopants formed in the second conductivity type region between the second diffusion layer and the first conductivity type region and electrically connected to the cathode,
wherein the first diffusion layer is disposed between the third diffusion layer and the second conductivity type region, and the second diffusion layer is disposed between the fourth diffusion layer and the first conductivity type region,
wherein the fifth diffusion layer is connected to the cathode through an external resistor.

16. The device as set forth in claim 15, wherein the anode is connected to a power source pad and the cathode is connected to a ground pad.

17. The device as set forth in claim 15, wherein the anode is connected to an input/output pad and the cathode is connected to a ground pad.

18. A device for protecting against electrostatic discharge, comprising:
first and second wells of first and second conductivity types formed in a substrate, contacting each other;
a second transistor formed over the first well;
a first transistor formed over the second well;
a first conductivity type guarding region formed in the first well between the second transistor and the second well; and
second conductivity type dopants guarding region formed in the second well between the first transistor and the first well,
wherein the first conductivity type dopants guarding region and a source of the second transistor are connected to a first power source, while the second conductivity type dopants guarding region and a source of the first transistor are connected to a second power source,
wherein external resistors are connected between the first guarding region and the first power source, and between the second conductivity type dopants guarding region and the second power source, respectively.

19. The device as set forth in claim 6, wherein the third and fourth diffusion layers are connected to an anode and a cathode through external resistors, respectively.

20. The device as set forth in claim 18, wherein:
the first conductivity type dopants is N-type;
the second conductivity type dopants is P-type;
the first transistor is an NMOS transistor; and
the second transistor is a PMOS transistor.

21. The device as set forth in claim 18, wherein:
the first power source provides a voltage VDD; and
the second power source provides a voltage VSS.

22. An ESD protection device comprising:
a substrate; and
at least one of the following formed in the substrate,
an _{F}^{S}FSF junction structure, where FS denotes a junction between a first (F) conductivity type region and a second (S) conductivity type region arranged electrically in series, and _{F}^{S}F denotes FF and SF junctions arranged electrically in parallel,
an SFS_{F}^{S} junction structure, where S_{F}^{S} denotes SS and SF junctions arranged electrically in parallel; and
an _{F}^{S}FS_{F}^{S} junction structure.

23. The device as set forth in claim 22, wherein:
the first conductivity type dopants is N-type; and
the second conductivity type dopants is P-type.

24. The device as set forth in claim 22, wherein at least one of the FF and the SS junctions is connected to a power source by an intervening an external resistor.
